(19) United States
(12) Patent Application Publication
(10) Pub. No.: US 2014/0284685 A1
(43) Pub. Date: Sep. 25, 2014

(54) NONVOLATILE SEMICONDUCTOR MEMORY DEVICE AND METHOD FOR MANUFACTURING SAME

(71) Applicant: Kabushiki Kaisha Toshiba, Minato-ku (JP)

(72) Inventors: Yoshiro SHIMOJO, Mie-ken (JP); Tsuneo Uenaka, Mie-ken (JP); Megumi Ishiduki, Mie-ken (JP); Mitsuru Sato, Mie-ken (JP)

(73) Assignee: Kabushiki Kaisha Toshiba, Minato-ku (JP)

(21) Appl. No.: 13/969,809

(22) Filed: Aug. 19, 2013

(30) Foreign Application Priority Data
Mar. 25, 2013 (JP) 2013-062984

(51) Int. Cl. H01L 29/792; H01L 21/28; H01L 29/66

(52) U.S. Cl. CPC H01L 29/792; H01L 29/66833; H01L 21/28282
USPC 257/324; 438/586

(57) ABSTRACT

According to one embodiment, a nonvolatile semiconductor memory device includes: a stacked body including each of a plurality of electrode layers and each of a plurality of insulating layers stacked alternately; a first interlayer insulating film; a select gate electrode; a second interlayer insulating film; a pair of semiconductor layers; a first insulating film; a second insulating film; a third interlayer insulating film; a first contact electrode connected to one upper end of the pair of semiconductor layers; a second contact electrode connected to the other upper end of the pair of semiconductor layers; a third contact electrode connected to the second contact electrode; a first interconnect layer connected to the first contact electrode; and a second interconnect layer connected to the third contact electrode.

### CROSS-REFERENCE TO RELATED APPLICATIONS

This application is based upon and claims the benefit of priority from Japanese Patent Application No. 2013-062984, filed on Mar. 25, 2013; the entire contents of which are incorporated herein by reference.

### FIELD

Embodiments described herein relate generally to a nonvolatile semiconductor memory device and a method for the same.

### BACKGROUND

A three-dimensional nonvolatile semiconductor memory device is known. In this device, a plurality of control electrode layers are stacked into a stacked body. A memory hole is formed in the stacked body. A memory film is formed on the sidewall of this memory hole. Furthermore, a channel body layer is formed on the sidewall of the memory film. In this kind of nonvolatile semiconductor memory device, a memory string is composed of the electrode layer, the memory film, and the channel body layer, and additionally a select gate and the like. Furthermore, the channel body layer is projected from the select gate. One end of the channel body layer is connected to a source line, and the other end is connected to a bit line via a contact electrode.

The length of the channel body layer between the select gate and the contact electrode is preferably made as short as possible from the viewpoint of memory hole processing, select gate formation and the like. On the other hand, if this length is made shorter, the contact electrode and the source line may be brought into contact with the select gate. This may degrade the reliability of the nonvolatile semiconductor memory device.

### BRIEF DESCRIPTION OF THE DRAWINGS

FIG. 1 is a schematic perspective view showing a memory cell array of a nonvolatile semiconductor memory device according to a first embodiment;

FIG. 2 is a schematic sectional view showing the memory cell section of the nonvolatile semiconductor memory device according to the first embodiment;

FIG. 3 is a schematic sectional view showing the structure of a select gate electrode, a contact electrode, a source line, and a bit line of the nonvolatile semiconductor memory device according to the first embodiment;

FIGS. 4A to 11B are schematic sectional views showing process for manufacturing the nonvolatile semiconductor memory device according to the first embodiment;

FIG. 12 is a schematic sectional view showing the structure of a select gate electrode, a source line, and a bit line of a nonvolatile semiconductor memory device according to a first reference example;

FIG. 13 is a schematic sectional view showing a structure of a select gate electrode, a contact electrode, a source line, and a bit line of a nonvolatile semiconductor memory device according to a second embodiment;

FIGS. 14A and 14B are schematic sectional views showing a process for manufacturing a nonvolatile semiconductor memory device according to a second reference example; and

FIGS. 15A and 15B are schematic sectional views showing a process for manufacturing the nonvolatile semiconductor memory device according to the second embodiment.

### DETAILED DESCRIPTION

In general, according to one embodiment, a nonvolatile semiconductor memory device includes: a foundation layer; a stacked body provided on the foundation layer and including each of a plurality of electrode layers and each of a plurality of insulating layers stacked alternately; a first interlayer insulating film provided on the stacked body; a select gate electrode provided on the first interlayer insulating film; a second interlayer insulating film provided on the select gate electrode; a pair of semiconductor layers extending from an upper end of the second interlayer insulating film to a lower end of the stacked body; a first insulating film provided between each of the pair of semiconductor layers and each of the plurality of electrode layers; a second insulating film provided between each of the pair of the semiconductor layers and the select gate electrode; a third interlayer insulating film provided on the second interlayer insulating film; a first contact electrode connected to one upper end of the pair of semiconductor layers and having a side surface surrounded with the third interlayer insulating film; a second contact electrode connected to the other upper end of the pair of semiconductor layers and having a side surface surrounded with the third interlayer insulating film; a third contact electrode connected to the second contact electrode and extending in stacking direction of the stacked body; a first interconnect layer connected to the first contact electrode and extending in a first direction generally perpendicular to the stacking direction; and a second interconnect layer connected to the third contact electrode and extending in a second direction generally perpendicular to the stacking direction and the second direction being crossing the first direction.

Embodiments will now be described with reference to the drawings. In the following description, like members are labeled with like reference numerals. The description of the members once described is omitted appropriately.

### First Embodiment

First, an overview of the structure of a nonvolatile semiconductor memory device 1 according to a first embodiment is described.

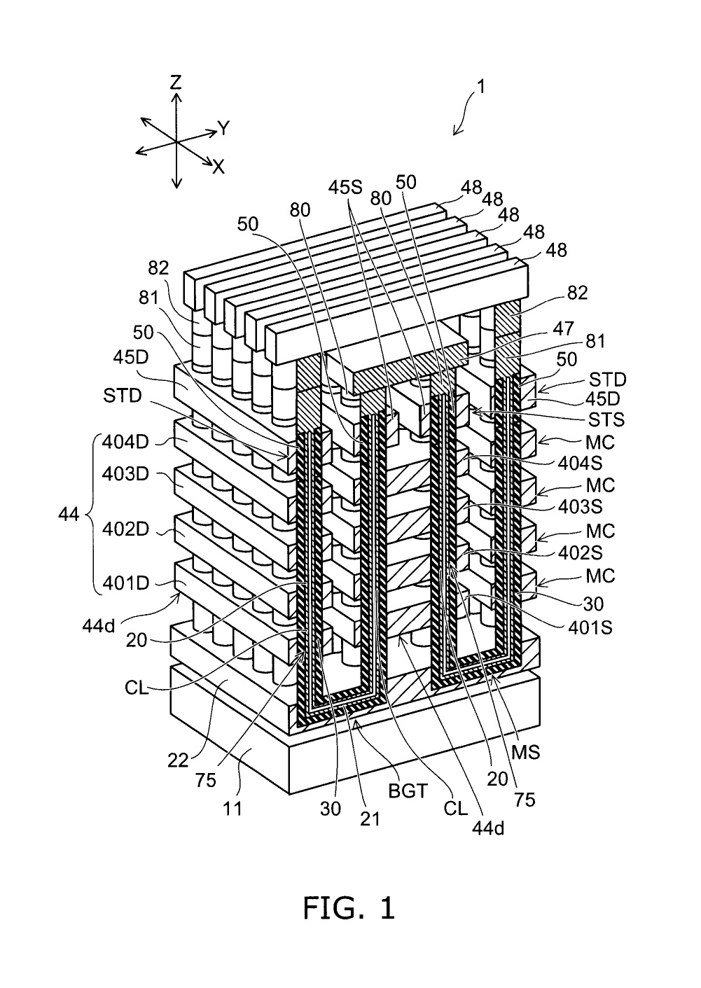

FIG. 1 is a schematic perspective view showing a memory cell array of the nonvolatile semiconductor memory device according to the first embodiment.

In FIG. 1, insulating portions other than the insulating film formed on the inner wall of the memory hole 75 are not shown. The nonvolatile semiconductor memory device 1 is a three-dimensionally stacked nonvolatile semiconductor memory device.

In FIG. 1, for convenience of description, an XYZ orthogonal coordinate system is introduced. In this coordinate system, two directions parallel to the major surface of the foundation layer 11 and orthogonal to each other are referred to as X direction and Y direction. The direction orthogonal to both these X and Y directions is referred to as Z direction.

FIG. 1 shows part of the memory cell array. In the actual nonvolatile semiconductor memory device 1, the memory cell array shown in FIG. 1 is repeated in the X direction and the Y direction.

The nonvolatile semiconductor memory device 1 is a nonvolatile semiconductor memory device capable of electrically and freely erasing/writing data and retaining its memory content even when powered off.

In the memory cell array of the nonvolatile semiconductor memory device 1, on a foundation layer 11, a semiconductor layer 22 (back gate layer) is provided via an insulating layer, not shown. The foundation layer 11 includes such as a semiconductor substrate (e.g., silicon substrate), an insulating layer (e.g., SiO₂ layer), and circuits. For instance, in the foundation layer 11, active elements such as transistors, and passive elements such as resistors and capacitors are provided. The semiconductor layer 22 is e.g. a silicon (Si) layer doped with an impurity element such as boron (B).

On the semiconductor layer 22, drain side electrode layers 401D, 402D, 403D, 404D and source side electrode layers 401S, 402S, 403S, 404S are stacked. In the Z direction, between these electrode layers, an insulating layer (not shown in FIG. 1) is provided. The material of the insulating layer 42 includes such as silicon oxide (SiO₂) and silicon nitride (Si₃N₄).

The electrode layer 401D and the electrode layer 401S are provided at the same level and represent first lowest electrode layers. The electrode layer 402D and the electrode layer 402S are provided at the same level and represent second lowest electrode layers. The electrode layer 403D and the electrode layer 403S are provided at the same level and represent third lowest electrode layers. The electrode layer 404D and the electrode layer 404S are provided at the same level and represent fourth lowest electrode layers.

The electrode layer 401D and the electrode layer 401S are divided in the Y direction. The electrode layer 402D and the electrode layer 402S are divided in the Y direction. The electrode layer 403D and the electrode layer 403S are divided in the Y direction. The electrode layer 404D and the electrode layer 404S are divided in the Y direction.

An insulating layer, not shown, is provided between the electrode layer 401D and the electrode layer 401S, between the electrode layer 402D and the electrode layer 402S, between the electrode layer 403D and the electrode layer 403S, and between the electrode layer 404D and the electrode layer 404S.

The electrode layers 401D, 402D, 403D, 404D are provided between the semiconductor layer 22 and a drain side select gate electrode 45D. The electrode layers 401S, 402S, 403S, 404S are provided between the semiconductor layer 22 and a source side select gate electrode 45S.

In the following description, the electrode layers 401D, 402D, 403D, 404D, 401S, 402S, 403S, 404S may also be simply referred to as electrode layers 40. The number of electrode layers 40 is arbitrary, and not limited to four layers illustrated in the first embodiment. Furthermore, the electrode layers 40 and the insulating layers 42 are collectively referred to as a stacked body 44. The lower surface of the first electrode layer 401D (or electrode layer 401S) constitutes the lower end 44d of the stacked body 44. The electrode layer 40 is e.g. a conductive silicon layer doped with an impurity element such as boron (B).

On the electrode layer 404D, a drain side select gate electrode 45D is provided via an insulating layer, not shown. The drain side select gate electrode 45D is e.g. a conductive silicon layer doped with impurity such as boron (B).

On the electrode layer 404S, a source side select gate electrode 45S is provided via an insulating layer, not shown. The source side select gate electrode 45S is e.g. a conductive silicon layer doped with impurity such as boron (B).

The drain side select gate electrode 45D and the source side select gate electrode 45S are divided in the Y direction. The drain side select gate electrode 45D and the source side select gate electrode 45S may also be simply referred to as select gate electrode 45 without distinction.

On the source side select gate electrode 45S, a source line 47 (first interconnect layer) is provided via an insulating layer, not shown. The source line 47 is connected through a contact electrode 80 to one end of a pair of channel body layers 20 (semiconductor layers). The material of the source line 47 is e.g. a metal such as tungsten (W) and copper (Cu), or conductive silicon doped with impurity.

On the drain side select gate electrode 45D and the source line 47, a plurality of bit lines 48 (second interconnect layers) are provided via an insulating layer, not shown. The material of the bit line 48 is e.g. a metal such as tungsten (W) and copper (Cu), or conductive silicon doped with impurity. The bit line 48 is connected through a contact electrode 81 and a contact electrode 82 to the other end of the pair of channel body layers 20. The bit line 48 extends in the Y direction. The material of the contact electrode 80, 81, 82 is e.g. a metal such as tungsten (W) and copper (Cu), or conductive silicon doped with impurity.

In the semiconductor layer 22 and the stacked body 44, a plurality of U-shaped memory holes 75 are provided. For instance, in the electrode layers 401D-404D and the drain side select gate electrode 45D, holes penetrating therethrough and extending in the Z direction are formed. In the electrode layers 401S-404S and the source side select gate electrode 45S, holes penetrating therethrough and extending in the Z direction are formed. A pair of the holes extending in the Z direction are linked via the semiconductor layer 22 to constitute a U-shaped memory hole 75. Here, besides the U-shaped memory hole, a straight memory hole is also encompassed within the scope of the embodiment.

Inside the memory hole 75, a channel body layer 20 is provided in a U-shape. The channel body layer 20 is e.g. a silicon-containing layer. This silicon refers to e.g. polysilicon, amorphous silicon and the like. Alternatively, the material of the channel body layer 20 may be tungsten (W). A memory film 30 (first insulating film) is provided between the channel body layer 20 and the inner wall of the memory hole 75. In other words, a memory film 30 is provided between each of a pair of channel body layers 20 and each of a plurality of electrode layers 40.

A gate insulating film 50 (second insulating film) is provided between the channel body layer 20 and the drain side select gate electrode 45D. A gate insulating film 50 is provided between the channel body layer 20 and the source side select gate electrode 45S.

Here, in the channel body layer 20, a void portion 20s is formed around the central axis of the channel body layer 20. However, the embodiment is not limited to this structure. As an alternative structure, the inside of the memory hole 75 may be entirely filled with the channel body layer 20 via the memory film 30 and the gate insulating film 50.

The drain side select gate electrode 45D, the channel body layer 20, and the gate insulating film 50 therebetween constitute a drain side select transistor STD. The channel body layer 20 above the drain side select transistor STD is electrically connected to a bit line 48.

The source side select gate electrode 45S, the channel body layer 20, and the gate insulating film 50 therebetween constitute a source side select transistor STS. The channel body layer 20 above the source side select transistor STS is electrically connected to a source line 47.

The drain side select transistor STD and the source side select transistor STS are cylindrical transistors.

The semiconductor layer 22, and the channel body layer 20 and the memory film 30 provided in the semiconductor layer 22, constitute a back gate layer transistor BGT.

A plurality of memory cells MC with the electrode layers 404D-401D serving as control gates are provided between the drain side select transistor STD and the back gate layer transistor BGT. Likewise, a plurality of memory cells MC with the electrode layers 401S-404S serving as control gates are provided also between the back gate layer transistor BGT and the source side select transistor STS.

The plurality of memory cells MC, the drain side select transistor STD, the back gate layer transistor BGT, and the source side select transistor STS are series connected via the channel body layer to constitute one U-shaped memory string (NAND string) MS.

One memory string MS includes a pair of columnar portions CL extending in the stacking direction of the stacked body 44 including a plurality of electrode layers 40, and a linking portion 21 embedded in the semiconductor layer 22 and linking the pair of columnar portions CL. The linking portion 21 includes a channel body layer 20. A plurality of such memory strings MS are arranged in the X direction and the Y direction. Thus, a plurality of memory cells are provided three-dimensionally in the X direction, the Y direction, and the Z direction.

The plurality of memory strings MS are provided on a memory cell array region in the foundation layer 11. Around the periphery, for instance, of the memory cell array region in the foundation layer 11, a peripheral circuit (not shown) for controlling the memory cell array is provided.

The nonvolatile semiconductor memory device 1 includes channel body layers 20 penetrating through the stacked electrode layers 40. The channel body layer 20 serves as a vertical semiconductor plug electrode. In the nonvolatile semiconductor memory device 1, the cross point of the electrode layer 40 and the channel body layer 20 is used as a memory element. In the nonvolatile semiconductor memory device 1, the lower ends of a pair of channel body layers 20 are connected by the linking portion 21. By the control of the select gate electrode 45 formed in each upper portion of the pair of channel body layers 20, a current is passed in the U-shaped semiconductor layer to read/erase data.

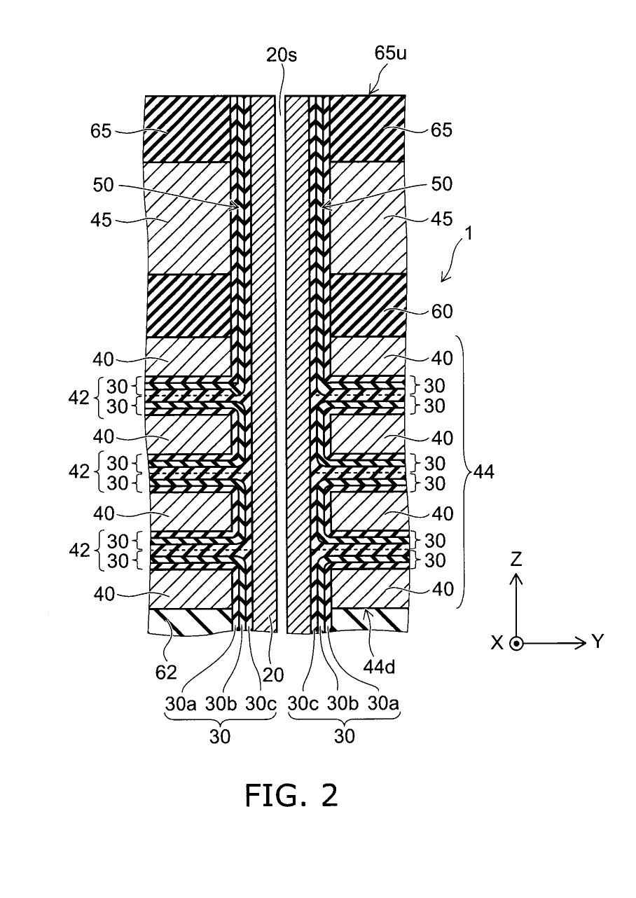

FIG. 2 is a schematic sectional view showing the memory cell section of the nonvolatile semiconductor memory device according to the first embodiment.

The nonvolatile semiconductor memory device 1 includes a foundation layer 11, a stacked body 44, a channel body layer 20, and a memory film 30. The stacked body 44 is provided on the foundation layer 11 (not shown in FIG. 2, see FIG. 1) via an interlayer insulating film 62. In the stacked body 44, a plurality of electrode layers 40 and a plurality of insulating layers 42 are stacked alternately one by one. In other words, each of a plurality of electrode layers 40 and each of a plurality of insulating layers 42 are stacked alternately. The interlayer insulating film 62 includes silicon oxide (SiO₂). On the stacked body 44, an interlayer insulating film 60 (first interlayer insulating film) is provided. The interlayer insulating film 60, 62 includes silicon oxide (SiO₂).

The memory film 30 is provided between the channel body layer 20 and each of the plurality of electrode layers 40. The memory film 30 is provided also between the channel body layer 20 and each of the plurality of insulating layers 42. The memory film 30 has a multilayer structure.

In the memory film 30, sequentially from the electrode layer 40 side toward the channel body layer 20, an oxide film 30a, a nitride film 30b, and an oxide film 30c are arranged. The nitride film 30b includes e.g. silicon nitride (Si₃N₄). The oxide film 30a, 30c includes e.g. silicon oxide (SiO₂). The memory film 30 has e.g. an ONO (oxide-nitride-oxide) structure in which a nitride film is sandwiched between a pair of oxide films. The insulating layer 42 sandwiched between the vertically adjacent electrode layers 40 is e.g. a stacked film including two ONO structures. The structure of the memory film 30 and the structure of the insulating layer 42 are not limited to this example.

The channel body layer 20 functions as a channel in a transistor constituting a memory cell. The electrode layer 40 functions as a control gate. The memory film 30 functions as a memory film of the nonvolatile semiconductor memory device 1. The nitride film 30b functions as a data memory layer for accumulating charge injected from the channel body layer 20.

On the interlayer insulating film 60, a select gate electrode 45 is provided. On the select gate electrode 45, an interlayer insulating film 65 (second interlayer insulating film) is provided. The interlayer insulating film 65 includes silicon oxide (SiO₂). A channel body layer 20 extends from the upper end 65u of the interlayer insulating film 65 to the lower end 44d of the stacked body 44.

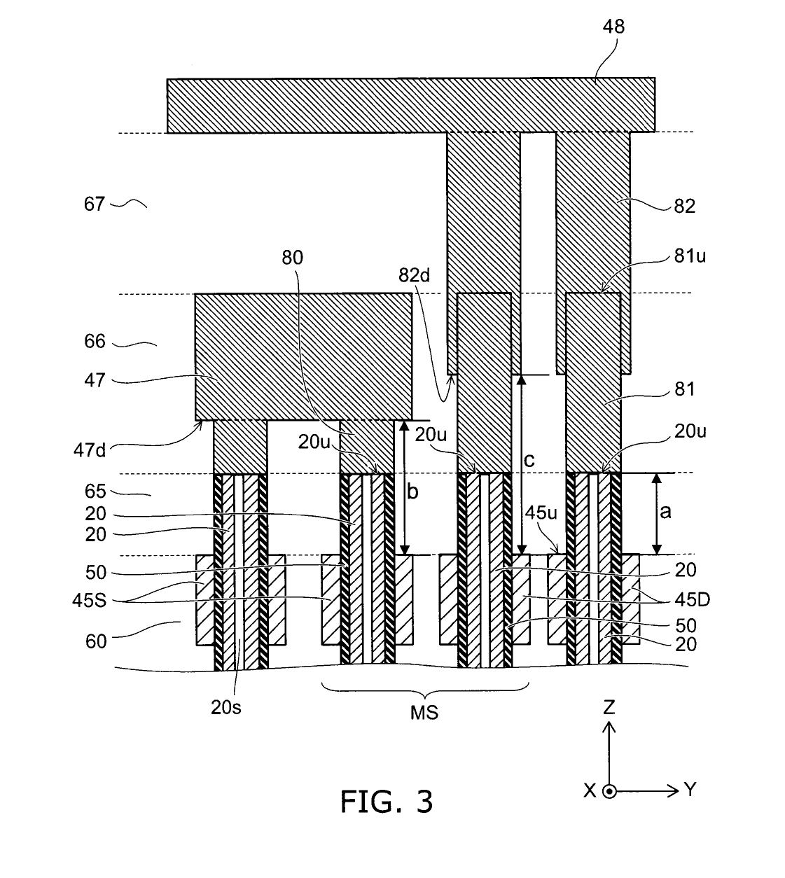

FIG. 3 is a schematic sectional view showing the structure of the select gate electrode, the contact electrode, the source line, and the bit line of the nonvolatile semiconductor memory device according to the first embodiment.

In FIG. 3, of a plurality of channel body layers 20, four channel body layers 20 are shown. Of these four channel body layers 20, the pair of the two middle channel body layers 20 constitute a U-shaped memory string MS. Near each upper portion of the two left channel body layers 20, a source side select gate electrode 45S is provided via a gate insulating film 50. Near each upper portion of the two right channel body layers 20, a drain side select gate electrode 45D is provided via a gate insulating film 50.

A contact electrode 80 (first contact electrode) is connected to one upper end 20u of a pair of channel body layers 20. The contact electrode 80 extends in the stacking direction of the stacked body 44 (Z direction). Furthermore, a contact electrode 81 (second contact electrode) is connected to the other upper end 20u of the pair of channel body layers 20. The contact electrode 81 extends in the stacking direction of the stacked body 44.

On the interlayer insulating film 65, an interlayer insulating film 66 (third interlayer insulating film) is provided. The side surface of the contact electrode 80 and the side surface of the contact electrode 81 are surrounded with the interlayer insulating film 66. To the contact electrode 81, a contact electrode 82 (third contact electrode) is further connected. The contact electrode 82 extends in the stacking direction of the stacked body 44. The outer diameter of the contact electrode 82 may be different from the outer diameter of the contact electrode 81. For instance, the outer diameter of the contact electrode 82 is larger than the outer diameter of the contact electrode 81.

To the contact electrode 80, a source line 47 is connected. The source line 47 extends in a direction (e.g., X direction) generally perpendicular to the stacking direction. The extending direction of the source line 47 is referred to as first direction. To the contact electrode 82, a bit line 48 is connected. The bit line 48 extends in a direction (e.g., Y direction) being generally perpendicular to the stacking direction and crossing the X direction. The extending direction of the bit line 48 is referred to as second direction. The length of the contact electrode 81 is longer than the length of the contact electrode 80 in the stacking direction. The upper end 81u of the contact electrode 81 is located at a higher position than the lower end 82d of the contact electrode 82.

On the interlayer insulating film 66, an interlayer insulating film 67 is provided. The interlayer insulating film 66, 67 includes silicon oxide (SiO₂). The distances a, b, c shown in FIG. 3 will be described later.

Next, a process for manufacturing the nonvolatile semiconductor memory device 1 is described.

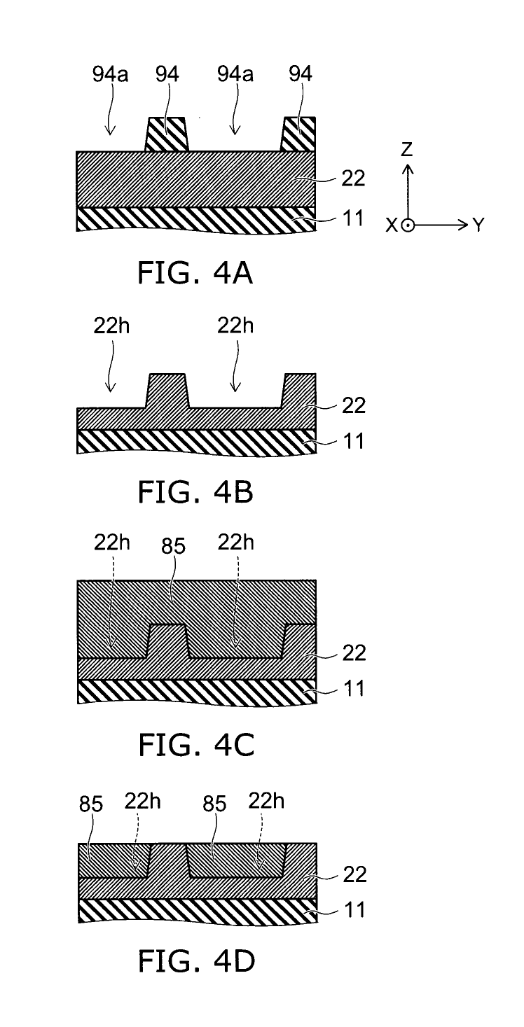

FIGS. 4A to 11B are schematic sectional views showing the process for manufacturing a nonvolatile semiconductor memory device according to the first embodiment.

Unless otherwise specified, the method for forming films and layers described below is appropriately selected from such as CVD (chemical vapor deposition), sputtering method, ALD (atomic layer deposition) method, epitaxial method, and spin coating method. The removal of films and layers and etching of films and layers are appropriately selected from dry etching such as RIE (reactive ion etching), wet etching with e.g. hydrofluoric acid solution or alkaline solution, and ashing with oxygen-containing gas.

First, as shown in FIG. 4A, a semiconductor layer 22 is formed on a foundation layer 11. Next, a mask pattern 94 is formed on the semiconductor layer 22. The material of the mask pattern 94 is a resist. The mask pattern 94 includes an opening 94a exposing part of the surface of the semiconductor layer 22.

Next, as shown in FIG. 4B, the semiconductor layer 22 exposed from the mask pattern 94 is dry etched. Thus, a recess 22h is formed in the semiconductor layer 22.

Next, as shown in FIG. 4C, a sacrificial layer 85 is formed on the semiconductor layer 22. For instance, the sacrificial layer 85 is formed in the recess 22h. The material of the sacrificial layer 85 is such as non-doped silicon and silicon nitride film. Then, the surface of the sacrificial layer 85 is etched back to expose the surface of the semiconductor layer 22. This state is shown in FIG. 4D.

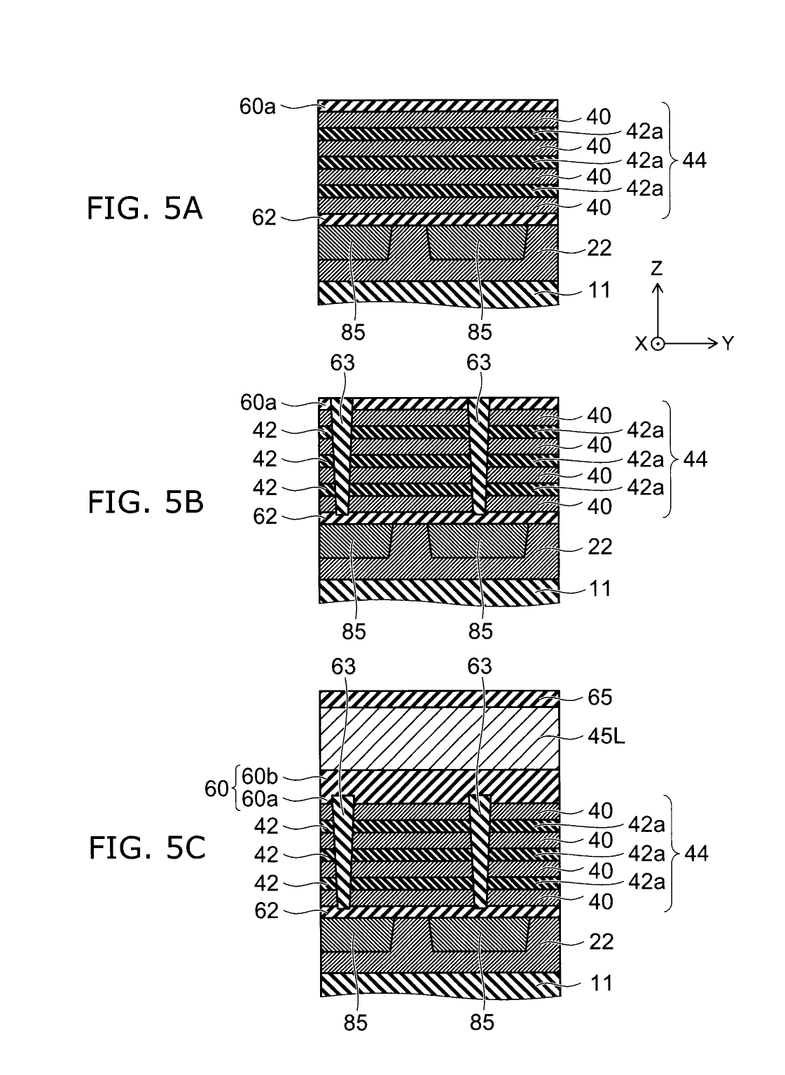

Next, as shown in FIG. 5A, an interlayer insulating film 62 is formed on the semiconductor layer 22 and on the sacrificial layer 85. Next, on the foundation layer 11, a stacked body 44 is formed via the interlayer insulating film 62. The stacked body 44 is a stacked body in which a plurality of electrode layers 40 and a plurality of sacrificial layers 42a are stacked alternately one by one. The material of the sacrificial layer 42a is such as non-doped silicon and silicon nitride film. Next, on the uppermost electrode layer 40, an insulating film 60a is formed.

Next, by photolithography and RIE, the insulating film 60a and the stacked body 44 are divided in the Y direction to form a trench (not shown) reaching the interlayer insulating film 62. In this trench, an insulating layer 63 is embedded. This state is shown in FIG. 5B.

FIG. 5B shows the state in which, for instance, by etch-back performed on the insulating layer 63, the upper end of the insulating layer 63 is made flush with the surface of the insulating film 60a. The insulating layer 63 extends in the X direction.

Next, as shown in FIG. 5C, on the stacked body 44, an insulating film 60b is formed via the insulating film 60a. Thus, on the stacked body 44, an interlayer insulating film 60 including the insulating films 60a, 60b is formed. Furthermore, on the interlayer insulating film 60, a select gate electrode layer 45L is formed. Next, on the select gate electrode layer 45L, an interlayer insulating film 65 is formed.

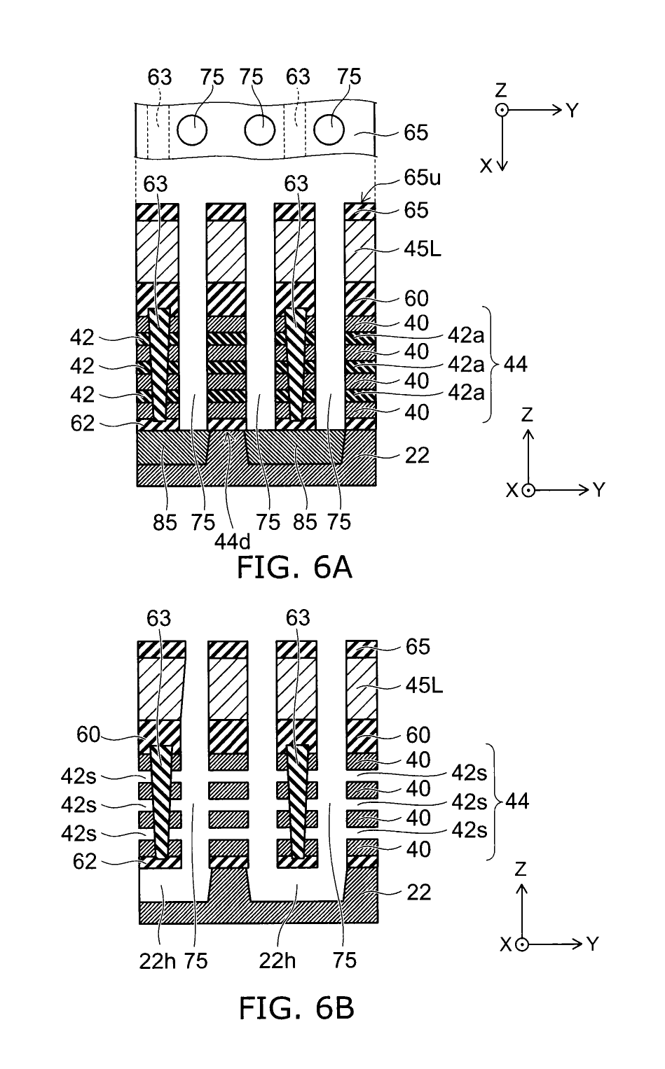

From FIG. 6A onward, the foundation layer 11 will not be shown in the figures.

Next, as shown in FIG. 6A, memory holes 75 penetrating through the interlayer insulating film 65, the select gate electrode layer 45L, the interlayer insulating film 60, and the stacked body 44 are formed by photolithography and RIE. Thus, a pair of memory holes 75 penetrating from the upper end 65u of the interlayer insulating film 65 to the lower end 44d of the stacked body 44 are formed. The memory hole 75 extends in the stacking direction of the stacked body 44 (Z direction). The pair of memory holes 75 are formed on the sacrificial layer 85 so as to sandwich the insulating layer 63 located generally at the center of the sacrificial layer 85.

In FIG. 6A, besides the schematic sectional view, a schematic top view is shown. The outline of the memory hole 75 cut along the X direction (or Y direction) is e.g. circular.

At the stage shown in FIG. 6A, each lower end of the pair of memory holes 75 reaches the sacrificial layer 85. That is, after RIE, the sacrificial layer 85 is exposed at the bottom of the memory hole 75.

Next, as shown in FIG. 6B, the sacrificial layer 85, 42a is removed through the memory hole 75 by e.g. wet etching. The etching liquid used for this removal is e.g. an alkaline chemical solution such as KOH (potassium hydroxide) solution, or phosphoric acid (H₃PO₄) solution with the etching rate adjusted by the temperature condition.

Thus, a recess 22h is formed again in the semiconductor layer 22. Furthermore, a space portion 42s is formed between the plurality of electrode layers 40. To the recess 22h, a pair of memory holes 75 are connected. That is, the respective lower ends of the pair of memory holes 75 are connected to the recess 22h to form a U-shaped memory hole 75.

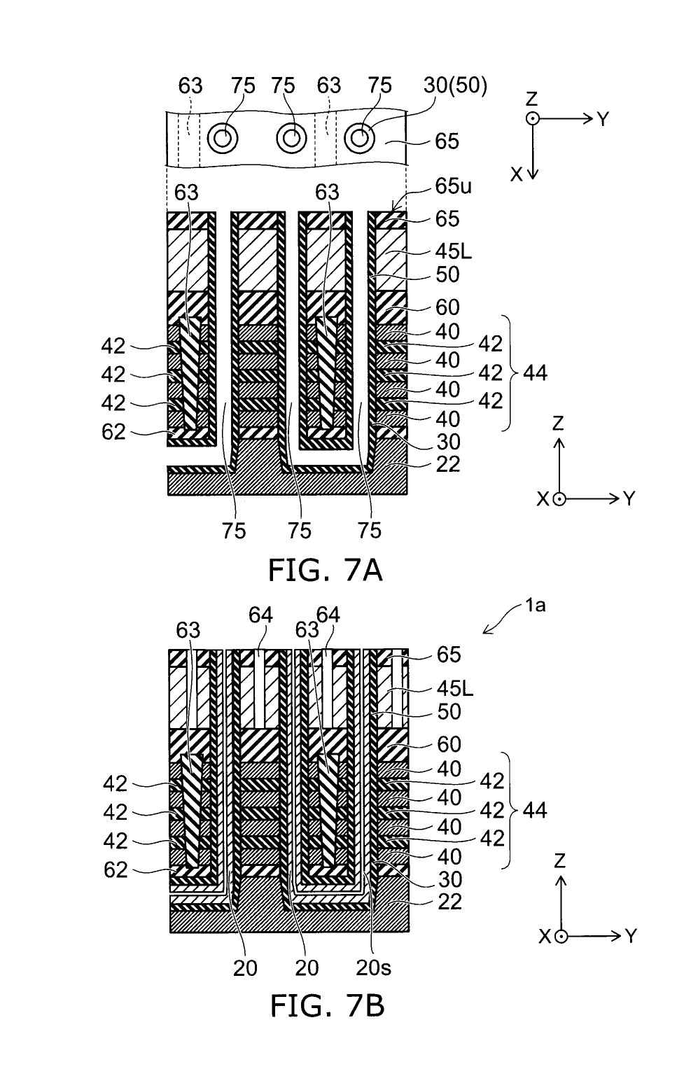

Next, as shown in FIG. 7A, inside the memory hole 75, a memory film 30 and a gate insulating film 50 are formed. For instance, on the sidewall of each of the pair of memory holes 75 and the recess 22h, a memory film 30 in contact with the stacked body 44, and a gate insulating film 50 in contact with the select gate electrode layer 45L are formed. The memory film 30 is formed also in the space portion 42s. Thus, an insulating layer 42 (memory film 30) is formed between the plurality of electrode layers 40.

Next, as shown in FIG. 7B, on the sidewall of each of the pair of memory holes 75, a channel body layer 20 is formed via the memory film 30 and the gate insulating film 50. Furthermore, an insulating layer 63 dividing the select gate electrode layer 45L is formed. By the provision of the insulating layer 63, a select gate electrode 45 is formed on the upper portion of the memory string MS.

At this stage, a structural body 1a including the foundation layer 11, the stacked body 44, the interlayer insulating films 60, 62, 65, the select gate electrode 45, the interlayer insulating film 65, a pair of channel body layers 20, the memory film 30, and the gate insulating film 50 is formed.

Here, the impurity concentration of the channel body layer 20 above the upper end 45u of the select gate electrode layer 45L may be made higher than the impurity concentration of the channel body layer 20 below the upper end 45u of the select gate electrode layer 45L. This is intended to increase the occurrence efficiency of GIDL (gate induced drain leakage) in the channel body layer 20 above the upper end 45u of the select gate electrode layer 45L. If GIDL is increased, the hole current is increased. This improves the erasure characteristics of the memory string.

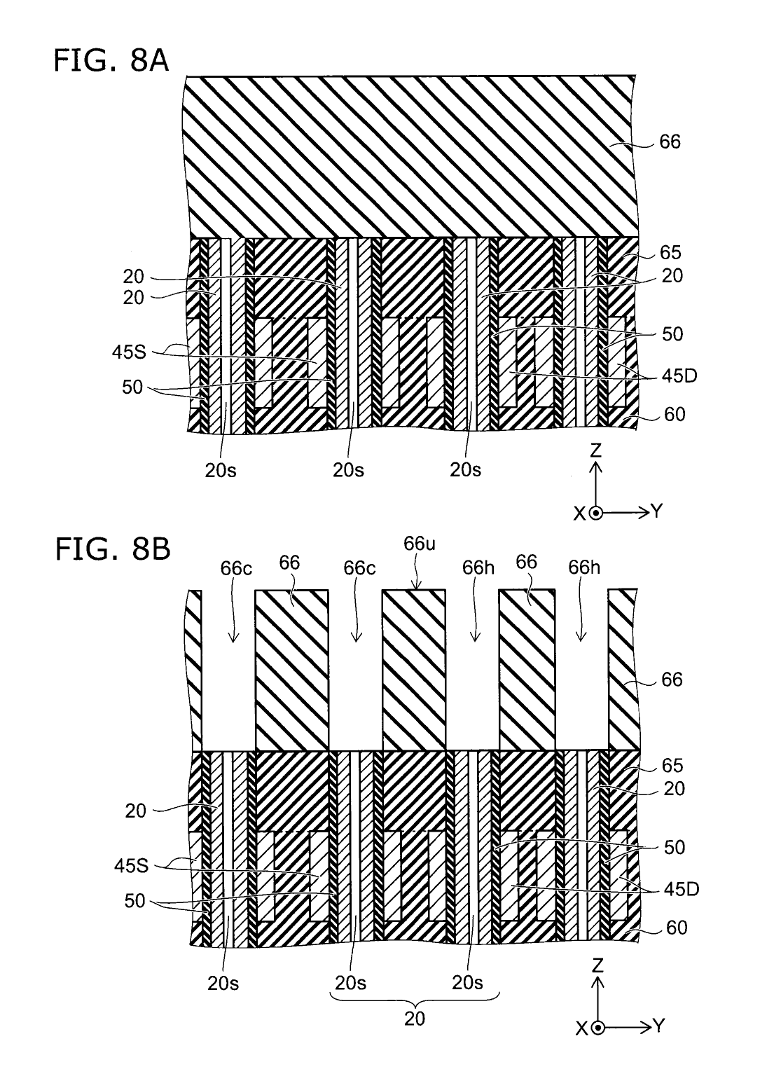

From FIG. 8A onward, the stacked body 44 below the select gate electrode 45 will not be shown in the figures.

Next, as shown in FIG. 8A, an interlayer insulating film 66 is formed on the interlayer insulating film 65, the gate insulating film 50, and the channel body layer 20.

Next, as shown in FIG. 8B, contact holes 66h (first contact holes) are formed by photolithography and RIE. For instance, in the stacking direction of the stacked body 44 (Z direction), a pair of contact holes 66h penetrating from the upper end 66u of the interlayer insulating film 66 to the pair of channel body layers 20, respectively, are formed. The pair of contact holes 66h correspond to the two middle contact holes 66h of the four contact holes 66h.

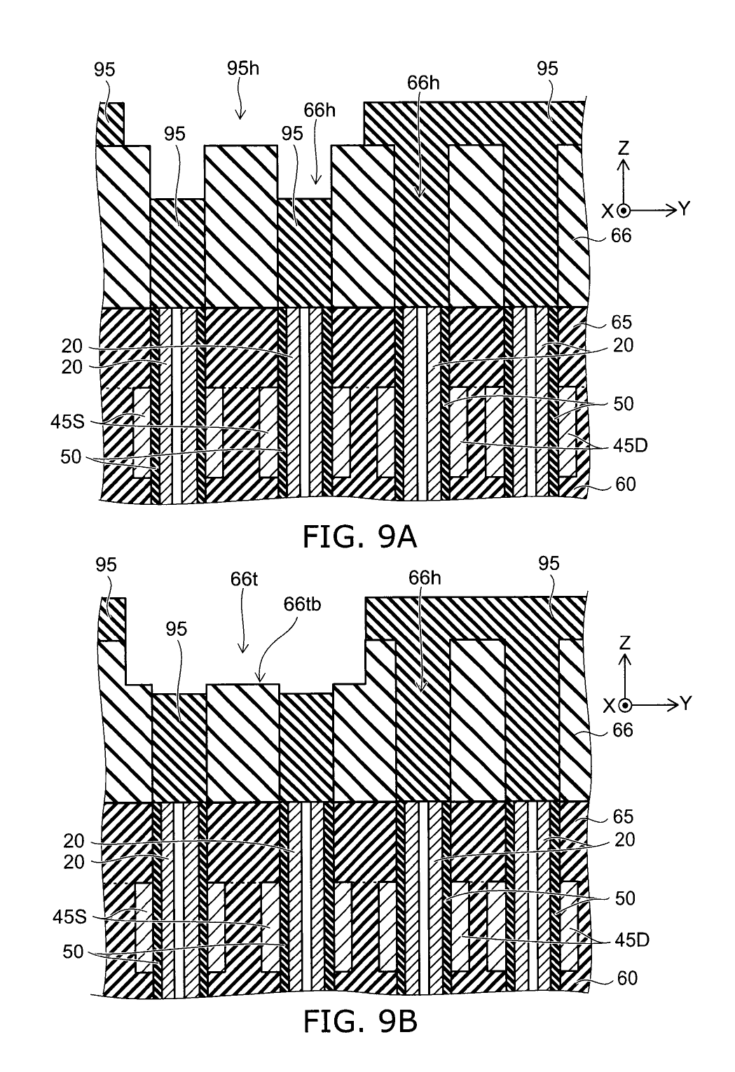

Next, as shown in FIG. 9A, a mask pattern 95 (CTL layer) is formed on the interlayer insulating film 66 and in the contact hole 66h. The mask pattern 95 includes an opening 95h. The opening 95h exposes the contact hole 66h above the source side select gate electrode 45S.

In the contact hole 66h below the opening 95h, the mask pattern 95 is not completely formed. For instance, the upper sidewall of the contact hole 66h below the opening 95h is exposed from the mask pattern 95. In the contact hole 66h above the drain side select gate electrode 45D, the mask pattern 95 is formed.

Next, as shown in FIG. 9B, the mask pattern 95 is used as a mask to perform dry etching on the interlayer insulating film 66. Thus, a trench 66t is formed in the interlayer insulating film 66. The trench 66t extends in the X direction. The trench 66t leads to the contact hole 66h below the opening 95h.

Suppose that at the stage of FIG. 9A, the mask pattern 95 is completely embedded in the contact hole 66h below the opening 95h. In this case, if the trench 66t is formed, a cylindrical mask pattern 95 is projected from the bottom 66tb of the trench 66t. This is because the etching rate of the mask pattern 95 is slower than the etching rate of the interlayer insulating film 66. To this projected portion, residues of the interlayer insulating film 66 generated at the time of etching may attach.

Thus, in the first embodiment, in the contact hole 66h below the opening 95h, the mask pattern 95 is not completely formed. After forming the trench 66t, the mask pattern 95 is removed by ashing (not shown).

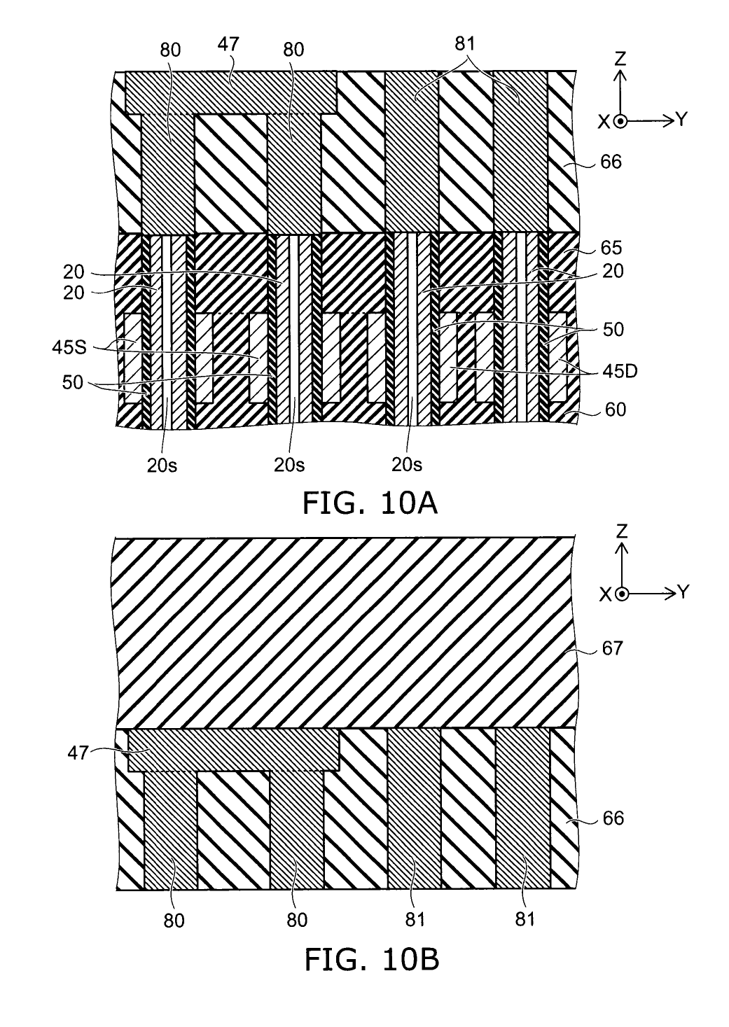

Next, as shown in FIG. 10A, in a pair of contact holes 66h, a contact electrode 80 and a contact electrode 81 are formed. Furthermore, in the trench 66t, a source line 47 is formed.

Above the source side select gate electrode 45S, the contact electrode 80 is formed in the contact hole 66h, and the source line 47 is formed in the trench 66t. The contact electrode 80, the contact electrode 81, and the source line 47 are simultaneously formed. The contact electrodes 80, 81 and the source line 47 are formed by e.g. plating method, CVD method, sputtering method, coating method or the like.

On the upper end of the contact electrodes 80, 81 and the upper end of the source line 47, CMP (chemical mechanical polishing) processing is performed as necessary. Thus, the upper end of the contact electrodes 80, 81, the upper end of the source line 47, and the upper end of the interlayer insulating film 66 are made flush. Furthermore, the length of the contact electrode 81 is longer than the length of the contact electrode 80 in the Z direction.

At this stage, one upper end of the pair of channel body layers 20 is in contact with the contact electrode 80. The other upper end of the pair of channel body layers 20 is in contact with the contact electrode 81. The source line 47 is in contact with the contact electrode 80. The source line 47 extends in the X direction.

From FIG. 10B onward, the portion below the channel body layer 20 will not be shown in the figures.

Next, as shown in FIG. 10B, an interlayer insulating film 67 (fourth interlayer insulating film) is formed on the interlayer insulating film 66, the source line 47, and the contact electrode 81.

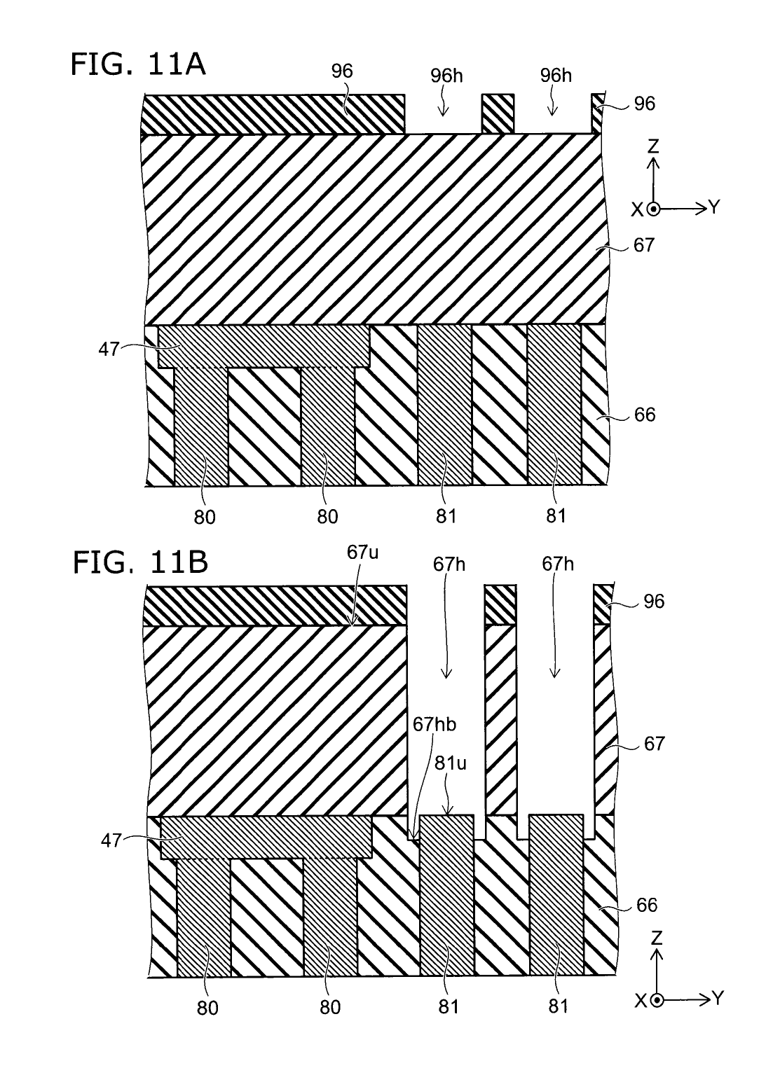

Next, as shown in FIG. 11A, a mask pattern 96 is formed on the interlayer insulating film 67. The mask pattern 96 includes an opening 96h. The opening 96h exposes the portion of the interlayer insulating film 67 above the contact electrode 81.

Next, as shown in FIG. 11B, a contact hole 67h (second contact hole) is formed in the interlayer insulating film 67. The contact hole 67h penetrates from the upper end 67u of the interlayer insulating film 67 to the upper end 81u of the contact electrode 81 in the Z direction. The etching for forming the contact hole 67h is based on what is called overetching. This is intended to secure the contact between the contact electrode 82 and the contact electrode 81, described later. For instance, the lower end 67hb of the contact hole 67h is adjusted to be made deeper than the upper end 81u of the contact electrode 81.

Subsequently, the mask pattern 96 is removed, and a contact electrode 82 is formed in the contact hole 67h. Thus, the contact electrode 82 is connected to the contact electrode 81. By the aforementioned overetching, the upper end 81u of the contact electrode 81 is located at a higher position than the lower end 82d of the contact electrode 82. Furthermore, on the interlayer insulating film 67, a bit line 48 is patterned. The bit line 48 is connected to the contact electrode 82. The bit line 48 extends in a direction (e.g., Y direction) being generally perpendicular to the Z direction and crossing the X direction. This state is shown in FIG. 3 described above.

Here, FIGS. 4A to 7B illustrate what is called the replacement process. By the replacement process, a sacrificial layer 42a is provided between the plurality of electrode layers 40, and after this sacrificial layer 42a is removed, an insulating layer 42 (memory film 30) is formed between the plurality of electrode layers 40.

In the manufacturing process of the first embodiment, instead of this replacement process, a stacked body 44 with a plurality of electrode layers 40 and a plurality of insulating layers 42 arranged alternately one by one may be previously formed on the foundation layer 11. Then, in this stacked body 44, a memory film 30 and a channel body layer 20 may be formed. In this case, the insulating layer 42 may be a monolayer silicon oxide layer.

Before describing the effect of the first embodiment, a reference example is illustrated.

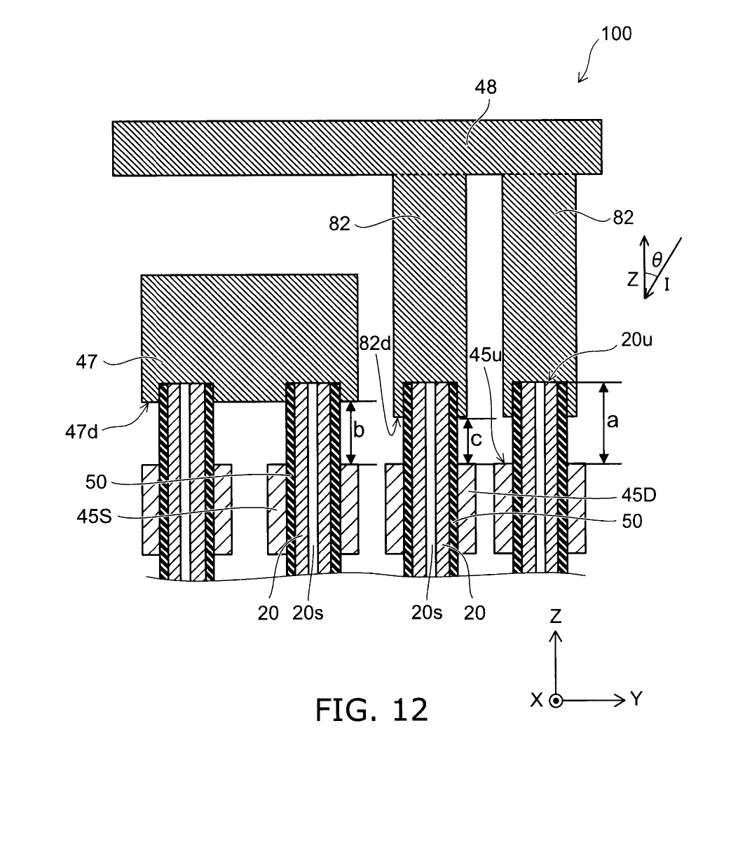

FIG. 12 is a schematic sectional view showing the structure of the select gate electrode, the source line, and the bit line of a nonvolatile semiconductor memory device according to a first reference example.

In the nonvolatile semiconductor memory device 100 according to the first reference example, the contact electrodes 80, 81 are not provided. Furthermore, the upper end 20u of the channel body layer 20 is located above the lower end 47d of the source line 47. Moreover, the upper end 20u of the channel body layer 20 is located above the lower end 82d of the contact electrode 82. The rest of the structure is the same as that of the nonvolatile semiconductor memory device 1.

As described above, in order to increase the occurrence efficiency of GIDL, the impurity concentration of the channel body layer 20 above the upper end 45u of the select gate electrode 45 (select gate electrode 45D or select gate electrode 45S) may be made higher than the impurity concentration of the channel body layer 20 below the upper end 45u. The adjustment of this impurity concentration is performed by e.g. ion implantation technique. Ion implantation is performed by the following procedure.

For instance, a resist layer is embedded in the void portion 20s below the upper end 45u of the select gate electrode 45. Next, an impurity element is implanted into the channel body layer 20 above the upper end 45u. The channel body layer 20 below the upper end 45u of the select gate electrode 45 is covered with the resist layer. Thus, the impurity element is implanted into the channel body layer 20 above the upper end 45u.

In the ion implantation, the impurity element is implanted into the sidewall of the channel body layer 20 above the upper end 45u of the select gate electrode 45. To this end, what is called the oblique ion implantation is used. That is, the impurity element is not injected parallel to the Z direction, but at a certain angle θ with respect to the Z direction. Here, “I” in the figure represents the direction of injection of the impurity element during ion implantation.

During ion implantation, the obliquely injected impurity element travels from the upper end 20u of the channel body layer 20 through the void portion 20s and reaches the channel body layer 20 above the upper end 45u of the select gate electrode 45.

In order to efficiently implant the impurity element into the sidewall of the channel body layer 20, the distance a between the upper end 20u of the channel body layer 20 and the upper end 45u of the select gate electrode 45 is preferably made as short as possible. This is because as the distance a becomes shorter, the angle θ of oblique ion implantation can be made larger.

Furthermore, making the distance a shorter facilitates depth control of the resist layer provided in the void portion 20s. Furthermore, making the distance a shorter facilitates processing of the memory hole 75.

However, as the distance a becomes shorter, the distance b between the lower end 47d of the source line 47 and the upper end 45u of the select gate electrode 45, and the distance c between the lower end 82d of the contact electrode 82 and the upper end 45u of the select gate electrode 45 become shorter. As the distance b becomes shorter, the source line 47 is made closer to the channel body layer 20. As the distance c becomes shorter, the contact electrode 82 is made closer to the channel body layer 20. Thus, electrical short circuit between the source line 47 and the select gate electrode 45S, or electrical short circuit between the contact electrode 82 and the select gate electrode 45D, is made more likely to occur.

In contrast, in the nonvolatile semiconductor memory device 1, the contact electrode 80 is interposed between the channel body layer 20 and the source line 47. Furthermore, the contact electrode 81 is interposed between the channel body layer 20 and the contact electrode 82.

Thus, in the nonvolatile semiconductor memory device 1, even if the distance a becomes shorter, the source line 47 is not made so close to the channel body layer 20, and the contact electrode 82 is not made so close to the channel body layer 20, as in the first reference example. The reason for this is as follows. Even if the distance a is made shorter, the distance b includes the length of the contact electrode 80. Furthermore, even if the distance a is made shorter, the distance c includes the distance between the lower end 82d of the contact electrode 82 and the upper end 20u of the channel body layer 20.

Thus, even if the distance a is made shorter, electrical short circuit between the source line 47 and the select gate electrode 45S, and electrical short circuit between the contact electrode 82 and the select gate electrode 45D, are less likely to occur. Accordingly, in the first embodiment, the reliability of the nonvolatile semiconductor memory device is improved.

### Second Embodiment

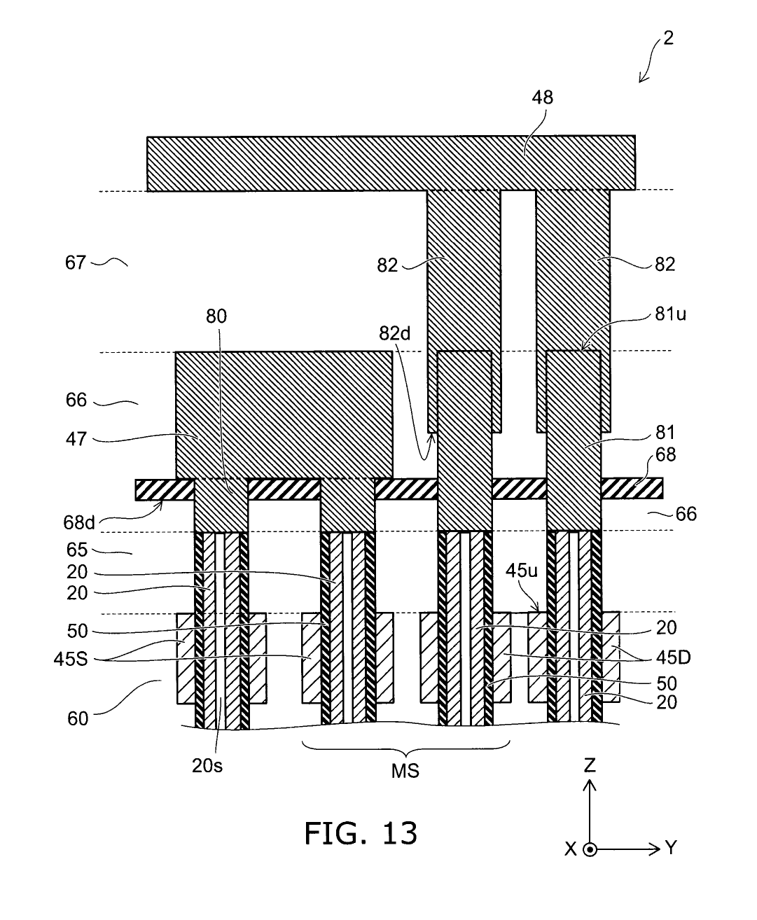

FIG. 13 is a schematic sectional view showing the structure of the select gate electrode, the contact electrode, the source line, and the bit line of a nonvolatile semiconductor memory device according to a second embodiment.

In the nonvolatile semiconductor memory device 2, an insulating film 68 (third insulating film) is provided above the interlayer insulating film 65. The insulating film 68 is sandwiched by the interlayer insulating film 66. After reaching the stage of FIG. 7B described above, an interlayer insulating film 66 is once formed. Next, an insulating film 68 is formed. Furthermore, the interlayer insulating film 66 is formed on the insulating film 68. The insulating film 68 includes a material different from the material of the interlayer insulating film 66. For instance, the insulating film 68 includes silicon nitride (Si₃N₄).

The insulating film 68 is located directly below the source line 47. For instance, the length from the upper end 45u of the select gate electrode 45 to the lower end 68d of the insulating film 68 is longer than the length from the upper end 45u of the select gate electrode 45 to each upper end 20u of the pair of channel body layers 20.

Before describing the effect of the second embodiment, a reference example is illustrated.

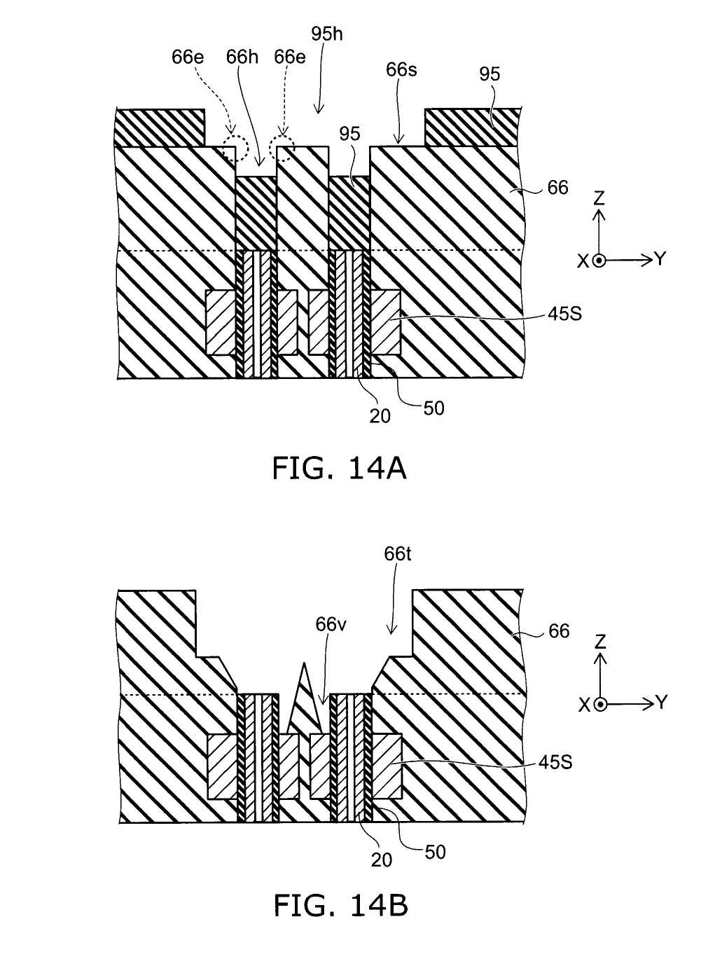

FIGS. 14A and 14B are schematic sectional views showing a process for manufacturing a nonvolatile semiconductor memory device according to a second reference example.

FIG. 14A shows the state in which the mask pattern 95 is formed on the interlayer insulating film 66 and in the contact hole 66h. The mask pattern 95 includes an opening 95h. The opening 95h exposes the contact hole 66h above the source side select gate electrode 45S.

In the contact hole 66h below the opening 95h, the mask pattern 95 is not completely formed. For instance, the upper sidewall of the contact hole 66h below the opening 95h is exposed from the mask pattern 95.

In this state, the mask pattern 95 is used as a mask to perform dry etching on the interlayer insulating film 66. However, in general, the edge portion 66e of the upper portion of the contact hole 66h has lower etching resistance than the surface 66s of the interlayer insulating film 66.

FIG. 14B shows one possible state after dry etching.

For instance, in the interlayer insulating film 66, a trench 66t is formed. In addition, a valley portion 66v may be formed. This valley portion 66v is formed by local overetching of the aforementioned edge portion 66e. As shown, the lower end of the valley portion 66v reaches the source side select gate electrode 45S.

In this state, if a source line 47 is formed in the trench 66t, the source line 47 is inserted into the valley portion 66v and causes short circuit between the source line 47 and the source side select gate electrode 45S.

The second embodiment eliminates the above possibility.

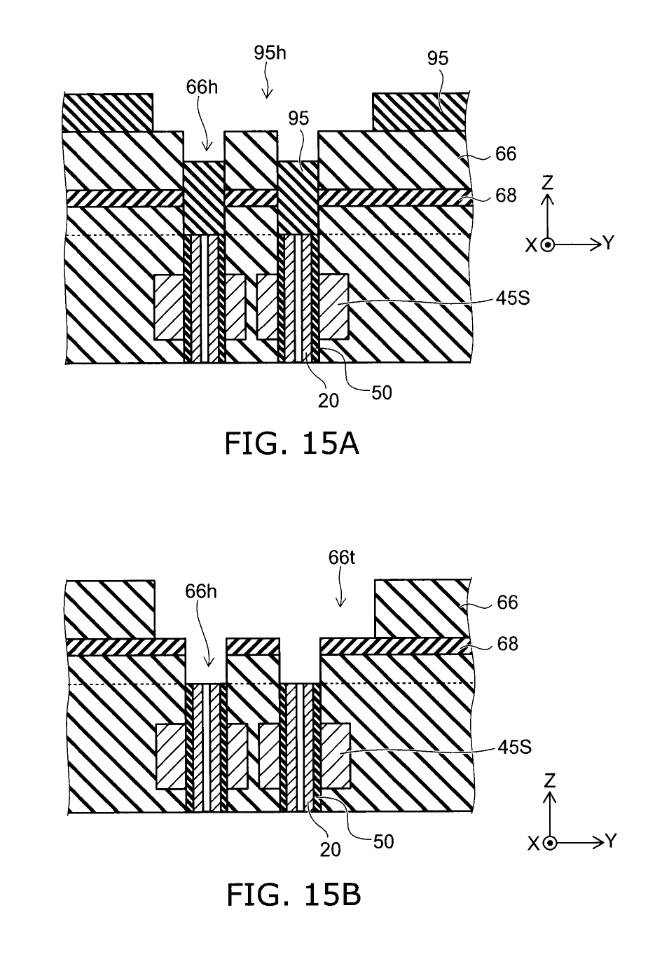

FIGS. 15A and 15B are schematic sectional views showing a process for manufacturing a nonvolatile semiconductor memory device according to the second embodiment.

As shown in FIG. 15A, in the second embodiment, in the interlayer insulating film 66, an insulating film 68 different in material from the interlayer insulating film 66 is provided. The material of the insulating film 68 includes a material having higher etching resistance than the interlayer insulating film 66. In this state, the mask pattern 95 is used as a mask to perform dry etching on the interlayer insulating film 66.

FIG. 15B shows the state after dry etching.

In the second embodiment, the insulating film 68 having higher etching resistance is provided in the interlayer insulating film 66. Thus, this insulating film 68 functions as a stopper film at the time of etching. Accordingly, at the time of dry etching, dry etching is blocked by the insulating film 68. Thus, the aforementioned valley portion 66v is not formed.

Then, even if a source line 47 is formed in the trench 66t, there is no problem such as insertion of the source line 47 into the valley portion 66v. That is, no short circuit occurs between the source line 47 and the source side select gate electrode 45S. This further improves the reliability of the nonvolatile semiconductor memory device.

The embodiments have been described above with reference to examples. However, the embodiments are not limited to these examples. More specifically, these examples can be appropriately modified in design by those skilled in the art. Such modifications are also encompassed within the scope of the embodiments as long as they include the features of the embodiments. The components included in the above examples and the layout, material, condition, shape, size and the like thereof are not limited to those illustrated, but can be appropriately modified.

Furthermore, the components included in the above embodiments can be combined as long as technically feasible. Such combinations are also encompassed within the scope of the embodiments as long as they include the features of the embodiments. In addition, those skilled in the art could conceive various modifications and variations within the spirit of the embodiments. It is understood that such modifications and variations are also encompassed within the scope of the embodiments.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

What is claimed is:

1. A nonvolatile semiconductor memory device comprising:
a foundation layer;
a stacked body provided on the foundation layer and including each of a plurality of electrode layers and each of a plurality of insulating layers stacked alternately;
a first interlayer insulating film provided on the stacked body;
a select gate electrode provided on the first interlayer insulating film;
a second interlayer insulating film provided on the select gate electrode;
a pair of semiconductor layers extending from an upper end of the second interlayer insulating film to a lower end of the stacked body;
a first insulating film provided between each of the pair of semiconductor layers and each of the plurality of electrode layers;
a second insulating film provided between each of the pair of the semiconductor layers and the select gate electrode;
a third interlayer insulating film provided on the second interlayer insulating film;
a first contact electrode connected to one upper end of the pair of semiconductor layers and having a side surface surrounded with the third interlayer insulating film;
a second contact electrode connected to the other upper end of the pair of semiconductor layers and having a side surface surrounded with the third interlayer insulating film;
a third contact electrode connected to the second contact electrode and extending in stacking direction of the stacked body;
a first interconnect layer connected to the first contact electrode and extending in a first direction generally perpendicular to the stacking direction; and
a second interconnect layer connected to the third contact electrode and extending in a second direction generally perpendicular to the stacking direction and the second direction being crossing the first direction.

2. The device according to claim 1, further comprising:
a third insulating film provided above the second interlayer insulating film and the third insulating film including a material different from a material of the third interlayer insulating film.

3. The device according to claim 2, wherein the third insulating film is located directly below the first interconnect layer.

4. The device according to claim 1, wherein length of the second contact electrode is longer than length of the first contact electrode in the stacking direction.

5. A method for manufacturing a nonvolatile semiconductor memory device, comprising:
(a) forming a structural body including a foundation layer, a stacked body provided on the foundation layer and including each of a plurality of electrode layers and each of a plurality of insulating layers stacked alternately, a first interlayer insulating film provided on the stacked body, a select gate electrode provided on the first interlayer insulating film, a second interlayer insulating film provided on the select gate electrode, a pair of semiconductor layers extending from an upper end of the second interlayer insulating film to a lower end of the stacked body, a first insulating film provided between each of the pair of semiconductor layers and each of the plurality of electrode layers, and a second insulating film provided between each of the pair of the semiconductor layers and the select gate electrode;
(b) forming a third interlayer insulating film on the second interlayer insulating film, the second insulating film, and the semiconductor layers;
(c) forming a pair of first contact holes penetrating from an upper end of the third interlayer insulating film to the pair of semiconductor layers in the stacking direction of the stacked body;
(d) forming a first contact electrode in contact with one upper end of the pair of semiconductor layers and a second contact electrode in contact with the other upper end of the pair of semiconductor layers in each of the pair of first contact holes, and further forming a first interconnect layer being in contact with the first contact electrode and extending in a first direction generally perpendicular to the stacking direction;
(e) forming a fourth interlayer insulating film on the third interlayer insulating film, the first interconnect layer, and the second contact electrode;
(f) forming a second contact hole penetrating from an upper end of the fourth interlayer insulating film to the second contact electrode in the stacking direction of the stacked body;
(g) forming a third contact electrode in contact with the second contact electrode in the second contact hole; and
(h) forming a second interconnect layer on the fourth interlayer insulating film, the second interconnect layer being in contact with the third contact electrode and extending in a second direction generally perpendicular to the stacking direction, and the second direction being crossing the first direction.

6. The method according to claim 5, wherein the step (c) includes, after forming the pair of first contact holes in the third interlayer insulating film, forming a trench in the third interlayer insulating film, and the trench leading to one of the first contact holes and extending in the first direction.

7. The method according to claim 6, wherein the step (d) includes forming the first contact electrode in one of the pair of first contact holes, and forming the first interconnect layer in the trench.

8. The method according to claim 5, further comprising:
forming a third insulating film including a material different from a material of the third interlayer insulating film above the second interlayer insulating film.

9. The method according to claim 5, wherein the step (d) includes simultaneously forming the first contact electrode, the second contact electrode, and the first interconnect layer.

10. The method according to claim 5, wherein length of the second contact electrode is made longer than length of the first contact electrode in the stacking direction.
